(19) United States
(12) Patent Application Publication
(10) Pub. No.: US 2006/0284301 A1
(43) Pub. Date: Dec. 21, 2006

(54) CSP semiconductor chip and BGA assembly with enhanced physical protection, protective members and assemblies used with same, and methods of enhancing physical protection of chips and assemblies

(76) Inventor: David J. Corisis, Nampa, ID (US)

Correspondence Address: TRASK BRITT, P.C., P.O. BOX 2550, SALT LAKE CITY, UT, 84110, US

(21) Appl. No.: 11/155,168

(22) Filed: Jun. 17, 2005

(51) Int. Cl. H01L 23/48

(52) U.S. Cl. 257/690

(57) ABSTRACT

Chip scale package semiconductor devices include a semiconductor chip and a protective member attached to an active surface of the semiconductor chip. At least one electrically conductive pad of the semiconductor chip is exposed through the protective member. The protective member includes a cantilevered portion that extends laterally beyond a lateral boundary of the semiconductor chip. Semiconductor device assemblies include such chip scale semiconductor devices and a higher level substrate. Semiconductor chip support structures include a substantially planar carrier member and at least one protective member removably coupled thereto and configured to protect at least a portion of an active surface of a semiconductor chip. Methods for packaging at least one semiconductor chip include providing a semiconductor chip and a protective member, and attaching the protective member to the semiconductor chip. Semiconductor chip support structures may be used to package and handle a plurality of semiconductor chips affixed to a like plurality of protective members.

### BACKGROUND OF THE INVENTION

1. Field of the Invention

The present invention relates to chip scale package (CSP) semiconductor devices that include a semiconductor chip and a protective member configured to protect at least a portion of an active surface of the semiconductor chip, and to semiconductor device assemblies that include such a CSP semiconductor device coupled to a higher level substrate. The present invention also relates to semiconductor chip support structures configured to support a plurality of semiconductor chips, the semiconductor chip support structures including a plurality of protective members configured to protect at least a portion of an active surface of each of the semiconductor chips. Furthermore, the present invention relates to methods for packaging semiconductor devices.

2. Description of Related Art

Semiconductor devices such as processors, memory, logic, and other devices may include an integrated circuit comprising a number of active and passive electronic components such as, for example, transistors, resistors, inductors and capacitors. These electronic components typically are formed, layer by layer, on or in a so-called “active” surface of a semiconductor wafer or other bulk semiconductor substrate using lithographic techniques.

When manufacturing semiconductor devices, a large plurality of semiconductor devices generally are formed on a single wafer or other bulk substrate comprising at least a layer of semiconductor material. The wafer then may be singulated to provide a plurality of individual semiconductor devices, which are often referred to as semiconductor “chips” or “dice.” The singulated chips may be attached to a higher level substrate, such as a carrier substrate in the form of a printed circuit board or an interposer substrate. Each semiconductor chip typically includes a plurality of electrically conductive pads, commonly termed “bond pads,” formed on the “active surface” of the semiconductor chip. The bond pads may communicate electrically with the electronic components of the integrated circuit of the semiconductor chip and may be used to electrically couple the electronic components of the integrated circuit with circuitry of a higher level substrate to which the semiconductor chip is attached as well as other chips and circuitry connected to the higher level substrate.

Many configurations of semiconductor chips are known in the art. The manner in which the bond pads of the semiconductor chip are electrically coupled to a higher level substrate may vary between configurations. These configurations include, for example, wire-bonded configurations, flip-chip configurations and ball grid array configurations (where a chip is mounted to an interposer). Wire bonded configurations may include a number of individual wires, one end of each wire being bonded to an electrically conductive pad (commonly termed a “bond pad”) on an active surface of a semiconductor chip, and an opposite end of each wire being bonded to either a lead finger or bus bar of a lead frame or to a terminal pad of a circuit trace of a board-type substrate. The lead fingers and bus bars of the leadframe or the substrate traces then may be attached to and electrically coupled with a higher level substrate. In flip chip configurations, a conductive structure such as a solder bump, a conductive or conductor-filled epoxy bump, or an anisotropically conductive adhesive, tape or film may be associated with each electrically conductive pad on the active surface of the semiconductor chip. The semiconductor chip then may be inverted or “flipped” relative to a surface of a higher level substrate such that the active surface of the chip is adjacent a surface of the higher level substrate. The pattern or array of conductive structures provided on the electrically conductive pads of the semiconductor chip may be electrically coupled with traces of circuitry of the higher level substrate to provide electrical communication between the higher level substrate and the integrated circuit of the semiconductor chip. In BGA assemblies, a chip may be mounted to an interposer substrate and, for example, wire bonded thereto, the connection to a higher level substrate being effected by conductive structures carried by the interposer.

A semiconductor chip 10 having a flip chip configuration is shown in FIGS. 1A and 1B. The semiconductor chip 10 may include an active surface 12. As seen in FIG. 1B, a plurality of electrically conductive pads 30 may be provided on or in the active surface 12 of the semiconductor chip 10. Furthermore, the electrically conductive pads 30 may be provided in a substantially central, conductive pad region 14 of the active surface 12 of the semiconductor chip 10. A plurality of electrically conductive bumps 20 may be provided on the plurality of electrically conductive pads 30. The electrically conductive bumps 20 may be configured as, for example, solder balls or conductive or conductor-filled epoxy bumps. Alternatively, an anisotropically conductive adhesive, tape or film that may be provided on the plurality of electrically conductive pads 30.

The conductive pad region 14 of the active surface 12 is considered to be the region or regions on the active surface 12 at which the conductive pads 30 are located, and may be approximately represented by the portion of the active surface 12 enclosed by the phantom line 18 shown in FIG. 1A. The phantom line 18 may substantially follow the periphery of the electrically conductive bumps 20 and the electrically conductive pads 30. A peripheral, pad-free region 16 of the active surface 12 of the semiconductor chip 10 is disposed outside the phantom line 18, which surrounds the conductive pad region 14 of the active surface 12. The pad-free region 16 of the active surface 12 is devoid of electrically conductive pads 30 and electrically conductive bumps 20.

The active surface 12 of the semiconductor chip 10 may be circumscribed by a lateral boundary 22 of the semiconductor chip 10 provided by the lateral sides of the semiconductor chip 10. As seen in FIG. 1B, the semiconductor chip 10 comprises a semiconductor substrate 26, which may include a passivated back side surface 28. The semiconductor chip 10 also may include an integrated circuit (not shown) fabricated in or on the active surface 12 and communicating electrically with at least some of the electrically conductive pads 30 and the corresponding electrically conductive bumps 20.

Semiconductor chips are relatively fragile and susceptible to damage. If the electronic components of the integrated circuit of a semiconductor chip are damaged, the chip may not function properly and, in some cases, may not function at all. Damage to a semiconductor chip may be caused during manufacturing processes performed subsequent to formation of the integrated circuit. Furthermore, damage may be caused by a variety of factors. For example, a semiconductor chip may be damaged by impact forces experienced during a pick and place operation, or by movement of the semiconductor chip within a tray used to support the semiconductor chip during handling between various fabrication, test and packaging processes.

The front, or active, surface of the semiconductor chip may be particularly susceptible to damage due to the presence of electronic components of the integrated circuit at or near the active surface. The back side surface of a singulated semiconductor device is somewhat remote from the electronic components and is also generally covered by a passivating layer, which may provide some degree of protection to the semiconductor substrate.

Furthermore, the edges of a semiconductor chip may be particularly susceptible to impact damage relative to substantially planar surfaces of the chip. Because stress is defined as force per unit area, the stress experienced by a semiconductor chip during impact with another object is at least partially a function of the impact force and the contact area over which the force is applied. When impact occurs along an edge of a semiconductor chip, and particular on a corner where three adjacent surfaces meet, the impact force is concentrated over a small area provided by the edge, which may result in relatively high magnitudes of stress in the semiconductor chip near the edge at which impact with the other object occurs.

A lesser, but significant potential for damage during handling and processing exists for BGA assemblies, wherein solder balls or other discrete conductive structures projecting from an interposer substrate may be damaged by contact with pick and place equipment.

Semiconductor chips may be packaged to protect the electronic structures of the integrated circuit of the semiconductor chip from damage. A semiconductor chip may be packaged by providing a polymer packaging material, such as a silicon-filled, thermoplastic resin, on one or more surfaces of the semiconductor chip. The chip may be substantially encapsulated by the packaging material. Means for providing electrical communication between the conductive pads and a higher level substrate, however, must be maintained or provided through the packaging material. Polymer packaging material may be applied to the chip using, for example, injection, transfer, or pot molding processes. As an alternative to polymer materials, a chip may be packaged in a preformed ceramic package or with any other protective material having suitable physical properties.

For many years, several factors have driven demand for providing semiconductor chips of ever decreasing size. Such factors include demand for smaller and lighter end-use devices, demand for increased information processing speeds, and demand for production of ever-larger numbers of devices from a single semiconductor wafer. As a result, bare semiconductor chips having no packaging have been used in electronic devices to eliminate the increase in physical dimensions of the semiconductor chips resulting from the packaging material itself. Bare semiconductor chips, however, do not benefit from the damage protection packaging material affords. As a result, protection of the semiconductor chip is often compromised at the expense of a desirable, smaller chip size, which may result in decreased yield from the fabrication process of devices that function properly. In an effort to balance the need for semiconductor chip protection with the demand for semiconductor chips of smaller size, some packaged semiconductor chips (often referred to as “chip scale packages”) that have physical dimensions only slightly larger than the bare semiconductor chip itself have been provided. These chip scale packages (CSP's) minimize the physical dimensions of the semiconductor chip package while affording some added protection of packaging material.

Because the active surface of the semiconductor chip typically is the region of the chip most susceptible to damage, it is desirable to provide packaging material or a protective layer to the active surface of a semiconductor chip without providing packaging material to other surfaces of the semiconductor chip. For example, U.S. Pat. No. 6,326,698, U.S. Pat. Nos. 6,544,821, and 6,861,763 each describe a CSP semiconductor device including a semiconductor chip similar to the semiconductor chip 10 shown in FIGS. 1A and 1B. The CSP semiconductor device includes protective layers formed by photolithography on the active surface of the semiconductor chip, through which contact pads are exposed. Photolithography, however, is a relatively expensive and somewhat time consuming process for forming layers of protective material. Furthermore, the protective layers of the CSP semiconductor devices described in the above referenced U.S. patents extend only to the lateral boundary of the semiconductor chip, which is provided by the lateral sides of the semiconductor chip. As a result, when impact occurs along the edges of the protective layers, the resulting damage occasionally may extend into a small area of the active surface near the edges of the semiconductor chip.

It would be desirable, therefore, to provide a CSP semiconductor device that includes a protective layer of material or a protective member on at least a portion of an active surface of a semiconductor chip to minimize damage to the active surface of the semiconductor chip without significantly enlarging the physical dimensions of the resulting chip package. Additionally, it would be desirable to provide such a protective layer of material or a protective member on at least a portion of an active surface of a semiconductor chip in an inexpensive manner. Furthermore, it would be desirable to provide a CSP semiconductor device including a protective layer of material or a protective member on at least a portion of an active surface of a semiconductor chip that provides enhanced protection to the edges of the active surface of the semiconductor chip without significant enlargement of the dimensions thereof.

### BRIEF SUMMARY OF THE INVENTION

The present invention, in a number of embodiments, all of which merely serve as nonlimiting examples of various manners of practicing the present invention, relates to chip scale package (CSP) semiconductor devices that include a semiconductor chip and a protective member for protecting at least a portion of an active surface of the semiconductor chip, assemblies including such CSP semiconductor devices, semiconductor chip support structures for supporting a plurality of semiconductor chips that include a plurality of protective members for protection of at least a portion of an active surface of each of the semiconductor chips, and to methods for protecting at least a portion of an active surface of a semiconductor chip.

One embodiment of the present invention comprises a CSP semiconductor device including a semiconductor chip having an active surface and a protective member attached to the active surface of the semiconductor chip. The active surface of the semiconductor chip is circumscribed by a lateral boundary of the semiconductor chip. At least one electrically conductive pad is disposed on the active surface of the semiconductor chip. The protective member includes a cantilevered portion that extends laterally beyond the lateral boundary of the semiconductor chip. The at least one electrically conductive pad of the semiconductor chip is exposed through an area or region at least partially circumscribed by the protective member.

In more particular embodiments of the present invention, the protective member may be planar or include non-planar features. Furthermore, the protective member may have a a rectangular frame shape, another polygonal shape, or may include, for example, a first C-shaped portion and a second C-shaped portion. The protective member may include a metal, a ceramic, or a polymer, and may comprise a single layer or multiple layers of material. The protective member, if at least partially formed of a conductive material, may also be used to provide electrical power to the semiconductor chip, to electrically ground the semiconductor chip, or both when the semiconductor chip is attached to a higher level substrate.

Another embodiment of the present invention comprises a semiconductor device assembly that includes a CSP semiconductor device attached to a higher level substrate. The CSP semiconductor device includes a semiconductor chip having an active surface and a protective member attached to the active surface of the semiconductor chip. The active surface of the semiconductor chip is circumscribed by a lateral boundary of the semiconductor chip. A plurality of electrically conductive pads is disposed on the active surface of the semiconductor chip. The plurality of electrically conductive pads is exposed through the protective member. The protective member includes a cantilevered portion that extends laterally beyond the lateral boundary of the semiconductor chip. The higher level substrate of the semiconductor device assembly includes a plurality of conductive structures. Electrically conductive pads of the semiconductor chip communicate electrically with associated conductive structures of the higher level substrate.

Yet another embodiment of the invention comprises a semiconductor chip support structure that includes a substantially planar carrier member and at least one protective member removably coupled to the substantially planar carrier member. The at least one protective member is configured to protect at least a portion of an active surface of a semiconductor chip and to expose at least one electrically conductive pad of the semiconductor chip through the protective member when the semiconductor chip is attached to the protective member. The protective member includes a cantilevered portion that is configured to extend laterally beyond a lateral boundary of the semiconductor chip. In one implementation, the semiconductor chip support structure comprises a plurality of protective members coupled to the substantially planar carrier member, which may be formed as a strip including indexing elements thereon to facilitate handling.

A further embodiment of the present invention comprises a method of packaging at least one semiconductor chip. At least one semiconductor chip is provided having an active surface. A protective member is provided and attached to the active surface of the semiconductor chip. The active surface of the semiconductor chip includes a conductive pad region and a pad-free region, and the protective member is attached to the active surface such that the protective member substantially covers the pad-free region of the active surface of the semiconductor chip and extends laterally beyond a substantial portion of a lateral boundary of the semiconductor chip. Furthermore, the protective member may define at least one open area in a central region thereof. The protective member may be integrally formed with a substantially planar carrier member including a plurality of protective members, and each protective member may be singulated from the substantially planar carrier member after affixation of a semiconductor chip thereto.

A still further embodiment of the present invention comprises a method of packaging at least one semiconductor chip. The method includes providing at least one semiconductor chip and at least one protective member. The at least one semiconductor chip includes an active surface that is circumscribed by a lateral boundary of the semiconductor chip. At least one electrically conductive pad is disposed on the active surface. The method further includes attaching the at least one protective member to the active surface of the at least one semiconductor chip such that the at least one electrically conductive pad is exposed and a portion of the at least one protective member extends laterally beyond the lateral boundary of the at least one semiconductor chip. A double-sided adhesive tape may be used to attach the at least one protective member to the active surface of the at least one semiconductor chip. Additionally, a packaging material may be provided on at least a portion of at least one of a back side surface and a lateral surface of the at least one semiconductor chip. In one implementation, the back side surface and lateral surfaces of the semiconductor chip may be covered with a relatively thin layer of packaging material, the packaging material abutting the protective member adjacent the active surface of the semiconductor chip.

Yet another embodiment of the present invention comprises a method of packaging a plurality of semiconductor devices. The method includes providing a semiconductor chip support structure that includes a substantially planar carrier member and a plurality of protective members coupled to the substantially planar carrier member, providing a plurality of semiconductor chips, and attaching each semiconductor chip to one protective member of the plurality of protective members. Each protective member is configured to protect at least a portion of an active surface of a semiconductor chip and to expose at least one electrically conductive pad of a semiconductor chip when a semiconductor chip is attached to the protective member. The protective member comprises a cantilevered portion configured to extend laterally beyond a lateral boundary of the semiconductor chip. Each semiconductor chip includes an active surface that is circumscribed by a lateral boundary of the semiconductor chip and a plurality of electrically conductive pads that is disposed on the active surface. Each semiconductor chip is attached to one protective member of the plurality of protective members such that at least one of the electrically conductive pads is exposed and a portion of the protective member extends laterally beyond the lateral boundary of the semiconductor chip. Each of the semiconductor chips may be singulated from the substantially planar carrier member of the semiconductor chip support structure together with the protective member that is attached to the semiconductor chip to provide a plurality of individual semiconductor devices.

A still further embodiment of the present invention encompasses a method of protecting a BGA assembly, and a BGA assembly incorporating a protective member according to the present invention.

The features, advantages, and alternative aspects of the present invention will be apparent to those skilled in the art from a consideration of the following detailed description taken in combination with the accompanying drawings.

### BRIEF DESCRIPTION OF THE SEVERAL VIEWS OF THE DRAWINGS

While the specification concludes with claims particularly pointing out and distinctly claiming that which is regarded as the present invention, the advantages of this invention may be more readily ascertained from the following description of the invention when read in conjunction with the accompanying drawings in which:

FIG. 1A is a top plan view of a semiconductor chip having a flip chip configuration as known in the art;

FIG. 1B is a cross-sectional view of the semiconductor chip shown in FIG. 1A taken along section line 1B-1B therein;

FIG. 2A is a top plan view of a semiconductor device that embodies teachings of the present invention;

FIG. 2B is a cross-sectional view of the semiconductor device shown in FIG. 2A taken along section line 2B-2B shown therein;

FIG. 2C is an enlarged view of a portion of the semiconductor device shown in FIG. 2B;

FIG. 3 is an enlarged view like that of FIG. 2C illustrating an additional implementation of a semiconductor device that embodies teachings of the present invention;

FIG. 4 is a cross-sectional view of a semiconductor device assembly that embodies teachings of the present invention and includes the semiconductor device shown in FIGS. 2A-2C and a higher level substrate;

FIG. 5 is a cross-sectional view like that of FIG. 4 illustrating another semiconductor device assembly similar to that shown in FIG. 4 further including packaging material at least partially covering a surface of a semiconductor chip;

FIG. 6A is a top plan view of a semiconductor chip support structure for supporting a plurality of semiconductor chips that embodies teachings of the present invention;

FIG. 6B is an enlarged view of a portion of the semiconductor chip support structure shown in FIG. 6A;

FIG. 7 is an enlarged view like that of FIG. 6B illustrating a portion of another semiconductor chip support structure that embodies teachings of the present invention;

FIG. 8 is a top plan view of another semiconductor device that embodies teachings of the present invention;

FIG. 9 is an enlarged view like that of FIG. 6B and FIG. 7 illustrating a portion of another semiconductor chip support structure that embodies teachings of the present invention;

FIG. 10 is a top plan view of another semiconductor device that embodies teachings of the present invention;

FIG. 11A is a top plan view of another semiconductor device that embodies teachings of the present invention;

FIG. 11B is a side view of the semiconductor device shown in FIG. 11A;

FIG. 11C is an end view of the semiconductor device shown in FIG. 11A;

FIG. 12 is a partial cross-sectional end view illustrating another semiconductor device assembly that embodies teachings of the present invention and includes the semiconductor device shown in FIGS. 11A-11C and a higher level substrate;

FIG. 13 is a cross-sectional view of another semiconductor device that embodies teachings of the present invention and includes the semiconductor device shown in FIGS. 2A-2C positioned within a recessed portion of a substrate; and

FIG. 14 is a side elevational view of a BGA assembly that embodies teachings of the present invention.

### DETAILED DESCRIPTION OF THE INVENTION

The present invention relates to chip scale package (CSP) semiconductor devices that include a semiconductor chip and a protective member configured to protect at least a portion of an active surface of the semiconductor chip, and to semiconductor device assemblies that include such a CSP semiconductor device coupled to a higher level substrate. The present invention also relates to semiconductor chip support structures configured to support a plurality of semiconductor chips, the semiconductor chip support structures including a plurality of protective members configured to protect at least a portion of an active surface of each of the semiconductor chips. Furthermore, the present invention relates to methods for packaging semiconductor devices.

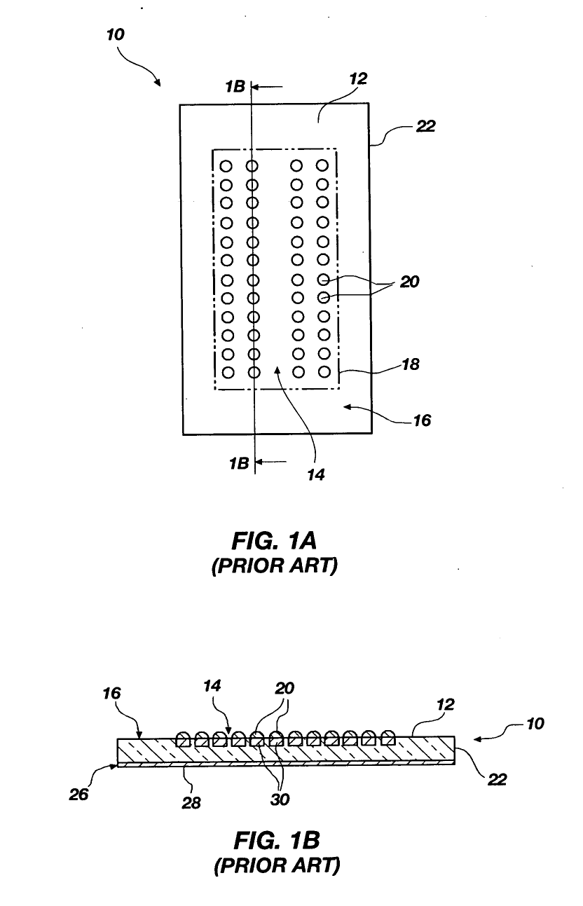

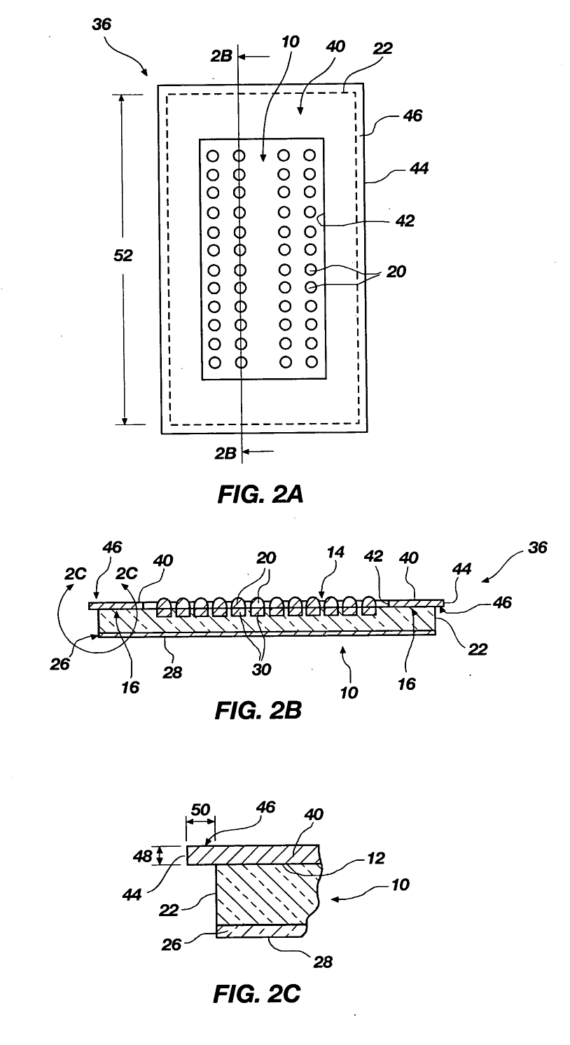

A CSP semiconductor device 36 is shown in FIGS. 2A-2C that embodies teachings of the present invention. The CSP semiconductor device 36 may include a semiconductor chip 10 such as that shown in FIGS. 1A-1B and a protective member 40. The protective member 40 may be attached to the active surface 12 of the semiconductor chip 10 and may be configured to protect at least a portion of the active surface 12 of the semiconductor chip 10. The protective member 40 may be configured to protect a pad-free region 16 of the active surface 12 of the semiconductor chip 10. Furthermore, the protective member 40 may be configured to expose a plurality of the electrically conductive pads 30 when the protective member 40 is attached to the semiconductor chip 10. In this configuration, the plurality of electrically conductive pads 30 may be exposed through the protective member 40 to allow for coupling of the electrically conductive pads 30 to electrical structures or circuitry of a higher level substrate.

As seen in FIG. 2A, the protective member 40 may have a rectangular, or “frame” shape substantially defined by an inner boundary 42 and a peripheral boundary 44. The inner boundary 42 of the protective member 40 may be continuous and may define a substantially central aperture extending through the protective member 40. The plurality of electrically conductive pads 30 may be exposed through this aperture when the protective member 40 is attached to the semiconductor chip 10. The peripheral boundary 44 of the protective member 40 also may be continuous or substantially continuous. The protective member 40 may include a cantilevered portion 46 that extends laterally beyond the lateral boundary 22 of the semiconductor chip 10. As shown in FIGS. 2A-2B, the cantilevered portion 46 of the protective member 40 may extend laterally beyond every point along the lateral boundary 22 of the semiconductor chip 10. Alternatively, the cantilevered portion 46 of the protective member 40 may extend laterally beyond a substantial section of the lateral boundary 22 of the semiconductor chip 10. For example, the cantilevered portion 46 of the protective member 40 may extend laterally beyond about 80 percent or more of the lateral boundary 22.

Referring to FIG. 2C, the protective member 40 may have a selected thickness 48. The selected thickness 48 may be selected considering the size of the electrically conductive bumps 20, which may be provided on the electrically conductive pads 30 of the semiconductor chip 10. For example, the selected thickness 48 of the protective member 40 may be slightly less than the distance the electrically conductive bumps 20 protrude or project from the active surface 12 of the semiconductor chip 10 in a direction substantially perpendicular thereto when the electrically conductive bumps 20 are provided on the electrically conductive pads 30 of the semiconductor chip 10. In this configuration, the protective member 40 will not preclude electrical contact or electrical communication between the electrically conductive bumps 20 and electrical structures or circuitry of a higher level substrate (not shown in FIGS. 2A-2C) to which the semiconductor chip 10 is to be attached. As a nonlimiting example, the selected thickness 48 of the protective member 40 may be less than about 70 microns when the electrically conductive bumps 20 are to extend from the active surface 12 of the semiconductor chip 10 in a direction substantially perpendicular thereto by a distance greater than about 70 microns.

As illustrated in FIG. 2C, the cantilevered portion 46 of the protective member 40 may extend laterally beyond at least a substantial portion of the lateral boundary 22 of the semiconductor chip 10 by a selected distance 50. In this configuration, the protective member 40 may protect a substantial portion of the active surface 12 of the semiconductor chip 10, including the edge defined by the intersection between the active surface 12 and the lateral boundary 22 of the semiconductor chip 10. For example, if the edge of the protective member 40 is damaged by impact with another object, the damage is not likely to extend to any portion of the active surface 12 of the semiconductor chip 10, including the edges of the semiconductor chip 10 defined by the intersection of the active surface 12 with the lateral boundary 22 provided by the lateral sides of the semiconductor chip 10 as well as the edges (corners) defined by two adjacent sides of semiconductor chip 10. This is so, at least partially due to the selected distance 50 by which the cantilevered portion 46 of the protective member 40 extends laterally beyond the lateral boundary 22 of the semiconductor chip 10, which selected distance 50 provides adequate separation between the outlying edges of protective member 40 and the inset edges of the active surface 12 relative to conventional CSP semiconductor devices. In this manner, the protective member 40 may protect portions of the active surface 12 of the semiconductor chip 10 that are particularly susceptible to damage.

The selected distance 50 by which the cantilevered portion 46 of the protective member 40 extends laterally beyond the lateral boundary 22 of the semiconductor chip 10 may be sufficiently small to retain characterization of the CSP semiconductor device 36 as a chip scale package. For example, the selected distance 50 may be selected such that any lateral dimension of the CSP semiconductor device 36 is no greater than about 1.2 times the corresponding lateral dimension of the semiconductor chip 10. For example, if the length 52 of the semiconductor chip 10 (FIG. 2A) is about 1,000 microns, the selected distance 50 may be about 100 microns, such that the corresponding length of the CSP semiconductor device 36 is less than about 1,200 microns, which is 1.2 times the length 52 of the semiconductor chip 10.

The protective member 40 may be attached to the semiconductor chip 10 using an adhesive, such as, for example, a curable epoxy material. For example, a curable liquid epoxy adhesive may be applied to either the protective member 40, to the semiconductor chip 10, or to both the protective member 40 and the semiconductor chip 10 prior to adjoining the protective member 40 with the semiconductor chip 10. The adhesive then may be cured to secure and attach the protective member 40 to the semiconductor chip 10. Depending on the particular adhesive used, the adhesive may be curable by heat, radiation, or by chemical reaction. One particularly suitable epoxy may comprise a so-called “B-stage” epoxy which is curable preliminarily to a tacky state to provide initial adhesion between active surface 12 and a surface of protective member 40. Many suitable adhesives are known in the art. Alternatively, the protective member 40 may be attached to the semiconductor chip 10 using alternative means, such as, for example, providing a mechanical fit between the protective member 40 and the semiconductor chip 10, providing a double sided adhesive-coated polyimide tape between the protective member 40 and the semiconductor chip 10, or by providing layer of material such as a thermoplastic material that will adhere to both the protective member 40 and the semiconductor chip 10 between the protective member 40 and the semiconductor chip 10 when heated sufficiently. Furthermore, the protective member 40 may be attached to the semiconductor chip 10 either prior to providing the electrically conductive bumps 20 on the electrically conductive pads 30 or subsequent to providing electrically conductive bumps 20 on the electrically conductive pads 30. If the semiconductor chip is “bumped” prior to singulation from a wafer, as is common practice, protective member will, of necessity, be attached after bumping and singulation of semiconductor chip 10 from the wafer.

The protective member 40 may be formed from a variety of materials including, for example, metals, ceramics, or polymer materials. In addition, material or materials used to form the protective member 40 may be at least partially selected based on their coefficient of thermal expansion such that the semiconductor chip 10 of the CSP semiconductor device 36 and attached protective member 40 exhibit compatible thermal expansion behavior. This may help to prevent or mitigate damage to the CSP semiconductor device 36 due to CTE-mismatch induced stress when the CSP semiconductor device 36 is subjected to fluctuations in temperature. It is also contemplated that an adhesive or other structure, such as the aforementioned polyimide film, may be used to mitigate adverse effects of CTE mismatch between protective member 40 and semiconductor chip 10.

The protective member 40 may be electrically conductive or electrically insulating. If the protective member 40 is electrically conductive, the protective member 40 or a portion of the protective member 40 may be used to electrically ground or bias the semiconductor chip 10 or to distribute power to the semiconductor chip 10 when the CSP semiconductor device 36 is attached to a higher level substrate. For example, the protective member 40 may be configured to provide electrical contact and communication between at least a region or a conductive pad of the semiconductor chip 10 and a higher level substrate (not shown in FIGS. 2A-2C) when the CSP semiconductor device 36 is attached to the higher level substrate. Furthermore, the protective member 40 may be configured to provide at least two electrically conductive regions or portions thereof, each electrically conductive region or portion being electrically isolated from the other electrically conductive region or portion. In such a configuration, one electrically conductive region or portion of the protective member 40 may be used to electrically ground or bias the semiconductor chip 10 and the other electrically conductive region or portion of the protective member 40 may be used to provide power to the semiconductor chip 10 through appropriate conductive pad or pads 30 when the CSP semiconductor device 36 is attached to a higher level substrate.

In this configuration, the protective member 40 may be attached to the semiconductor chip 10 such that the protective member 40 substantially covers and protects a pad-free region 16 (FIG. 1A) of the active surface 12 of the semiconductor chip 10. In addition, a plurality of the electrically conductive pads 30 may be exposed through the aperture of the protective member 40 defined by the substantially continuous inner boundary 42 when the protective member 40 is attached to the semiconductor chip 10. In this manner, the protective member 40 is configured to protect at least a portion of the active surface 12 of the semiconductor chip 10 and to expose a plurality of the electrically conductive pads 30 when the protective member 40 is attached to the semiconductor chip 10.

As described previously herein, the protective member 40 may be configured to protect areas of the active surface 12 that are substantially free of electrically conductive pads 30 and electrically conductive bumps 20, such as the pad-free region 16 of the active surface 12 of the semiconductor chip 10 shown in FIGS 1A-1B. The areas of the active surface 12 that are substantally free of electrically conductive pads 30 and electrically conductive bumps 20 are disposed along the periphery of the active surface 12 are near the lateral boundary 22 of the semiconductor chip 10. Accordingly, the protective member 40 shown in FIGS. 2A-2C is shown configured to protect these peripheral regions of the active surface 12 of the semiconductor chip. It should be understood that semiconductor chips are produced that have configurations other than that represented by the semiconductor chip 10 shown in FIGS. 1A-1B, and that protective members embodying teachings of the present invention may be configured to complement such other configurations of semiconductor chips. In each configuration, the protective member may be configured to cover at least a portion of the active surface of the semiconductor chip while exposing a plurality of electrically conductive pads of the semiconductor chip through the protective member. Furthermore, the protective member may include a cantilevered portion that extends laterally beyond the lateral boundary of the semiconductor chip in each configuration. In addition, protective members that embody teachings of the present invention may be used with other configurations of CSP semiconductor devices including, for example, wire-bonded configurations in addition to flip-chip configurations.

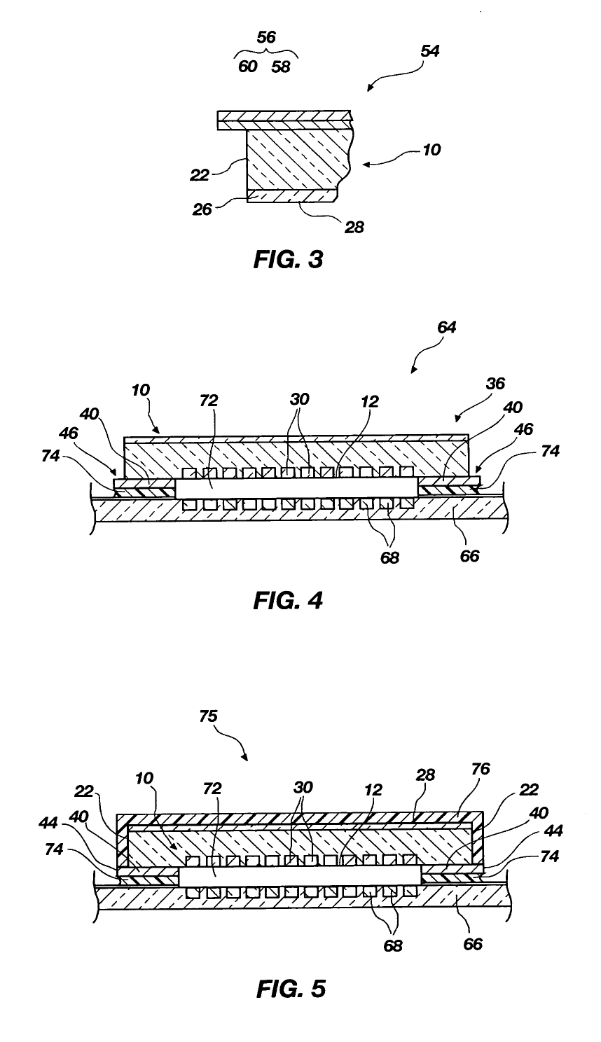

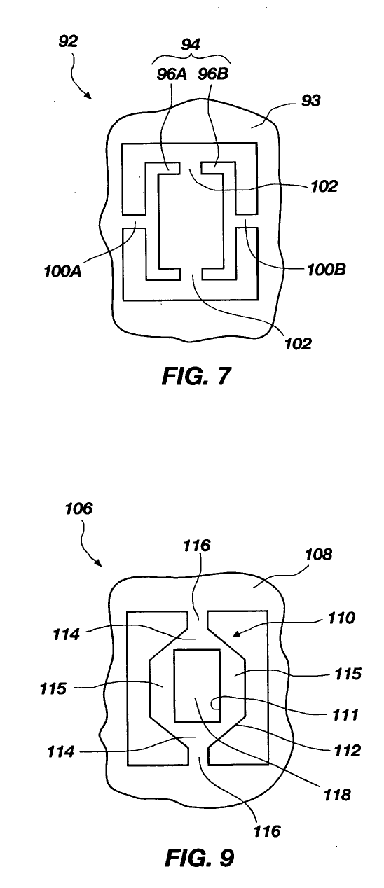

A portion of another CSP semiconductor device 54 that embodies teachings of the present invention is shown in FIG. 3, which is an enlarged partial view like that of FIG. 2C. As shown in FIG. 3, the CSP semiconductor device 54 may include the semiconductor chip 10 shown in FIGS. 1A-1C and a protective member 56 having a laminate structure. The protective member 56 may be substantially similar to the protective member 40 in all other aspects. The laminate structure of the protective member 56 may include a layer 58 of protective material and a layer 60 of adhesive material or a polymer film bearing adhesive on both sides. In such a manner, layer 58 of protective material may comprise an electrically conductive material by which power or bias may be applied to semiconductor chip 10 and, if protective member 56 is segmented (see FIGS. 7-9) the electrically isolated portions may be employed to achieve both such functions. Further, the laminate structure of the protective member 56 may include multiple layers of different materials, each layer configured to provide desired electrical, mechanical, or other physical properties to the overall laminate structure. For example, one layer may be configured to be electrically insulating and one or more adjacent other layers may be configured to be electrically conductive. Yet another layer may be configured to provide hardness for resistance to impact damage and high flexural modulus for resistance to bending of the protective member 56 and the semiconductor chip 10. Furthermore, each layer of material, or combination of layers, may be selected to exhibit a selected coefficient of thermal expansion to prevent or mitigate damage to the CSP semiconductor device 54 due to thermal expansion mismatch when the CSP semiconductor device 54 is subjected to fluctuations in temperature.

CSP semiconductor devices that embody teachings of the present invention, such as, for example, the CSP semiconductor device 36 shown in FIGS. 2A-2C, may be attached to a higher level substrate. A semiconductor device assembly 64 that embodies teachings of the present invention is shown in FIG. 4 that includes the CSP semiconductor device 36 shown in FIGS. 2A-2C attached to a higher level substrate 66. The higher level substrate 66 may be, for example, a carrier substrate in the form of, for example, a printed circuit board or an interposer.

The CSP semiconductor device 36 is shown in FIG. 4 to include an anisotropically conductive tape or film 72 disposed over conductive pads 30 instead of electrically conductive bumps 20 shown in FIGS. 2A-2B. The anisotropically conductive tape or film 72 is configured, as known in the art, to conduct electricity only in a direction substantially perpendicular to the plane of the tape or film 72 and, thus, of active surface 12 of the semiconductor chip 10, to prevent shorting between laterally adjacent conductive pads 30. In this configuration, each electrically conductive pad 30 of the semiconductor chip may communicate electrically with an electrically conductive structure 68, such as a conductive trace, of the higher level substrate 66. Alternatively, the electrically conductive bumps 20 shown in FIGS. 2A-2B may be used instead of the anisotropically conductive tape 72 to provide electrical communication between the electrically conductive pads 30 of the semiconductor chip 10 and corresponding electrically conductive structures 68 of the higher level substrate 66. The conductive structures 68 of the higher level substrate 66 may be configured as terminal pads, contact pads, electrical traces, or any other electrically conductive feature. Although not illustrated in FIG. 4, it should be understood that each electrically conductive structure 68 of the higher level substrate 66 may communicate electrically with conductive traces or active or passive components incorporated in or coupled to an electrical circuit of the higher level substrate.

As shown in FIG. 4, the CSP semiconductor device 36 may be coupled to the higher level substrate 66 not only by anisotropic conductive tape or film 72 or conductive bumps 20, but also by, for example, using a dielectric adhesive 74 that may be applied either to the protective member 40, to the higher level substrate 66, or to both the protective member 40 and the higher level substrate 66 prior to adjoining the CSP semiconductor device 36 with the higher level substrate 66. Furthermore, the protective member 40 may be configured to be wettable relative to the adhesive 74. For example, a layer of material that is wettable relative to the adhesive 74 may be applied to a surface of the protective member 40 prior to adjoining the CSP semiconductor device 36 to the higher level substrate 66. Alternatively, the protective member 40 may be constructed from a material that is wettable relative to the adhesive 74. By providing a protective member 40 that is configured to be wettable relative to the adhesive 74, the surface area of the protective member 40 that is bonded to the higher level substrate 66 may be increased and consequent enhanced bonding as well as environmental protection provided, which may eliminate the need for providing a dielectric underfill between the CSP semiconductor device 36 and the higher level substrate 66, as is often done conventionally when attaching a semiconductor chip or package to a higher level substrate.

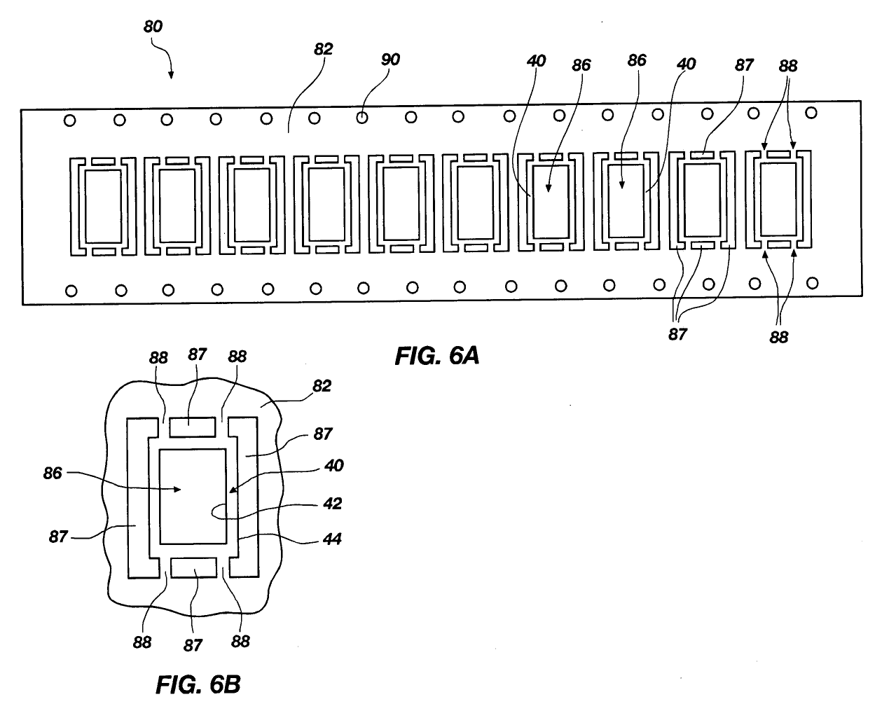

Devices that embody teachings of the present invention, such as the CSP semiconductor device 36 shown in FIGS. 2A-2C and the semiconductor device assembly 64 shown in FIG. 4, may include a layer of packaging material covering at least a portion of a semiconductor chip. For example, FIG. 5 illustrates another semiconductor device assembly 75 that embodies teachings of the present invention that includes a packaging material 76 covering at least a portion of a semiconductor chip 10. In all other aspects, the semiconductor device assembly 75 may be substantially similar to the semiconductor device assembly 64 shown in FIG. 4. The packaging material 76, in a relatively thin layer, covers the passivated, back side surface 28 and the lateral boundary 22 provided by the lateral sides of the semiconductor chip 10. Furthermore, the packaging material 76 may not extend laterally beyond the peripheral boundary 44 of the protective member 40 and, as shown in FIG. 5, may have an outer surface substantially coincident therewith. The packaging material 76 may be a polymer material and may be applied to the semiconductor chip 10 using, for example, injection, transfer, or pot molding processes or the semiconductor chip 10 may be dipped or spray-coated with the packaging material 76. Furthermore, the packaging material 76 may be applied to the semiconductor chip 1 0 either before or after securing the protective member 40 to the active surface 12 of the semiconductor chip 10. As an alternative to polymer materials, the packaging material 76 may include any other protective material having suitable physical properties.

To form devices that embody teachings of the present invention, such as the CSP semiconductor device 36 shown in FIGS. 2A-2C and the semiconductor device assembly 64 shown in FIG. 4, individual protective members such as protective member 40 may be formed and attached to an individual semiconductor chip such as the semiconductor chip 10. Alternatively and for enhanced efficiency of processing and handling, a semiconductor chip support structure that includes a plurality of protective members integrally formed therewith may be formed or provided, and a plurality of semiconductor chips may be attached to the semiconductor chip support structure, one semiconductor chip being attached to each of the protective members to form a plurality of CSP semiconductor devices on the semiconductor chip support structure. Subsequently, each CSP semiconductor device may be singulated, as by punching or cutting an individual protective member 40 secured to a semiconductor chip 10, from the semiconductor chip support structure. A semiconductor chip support structure 80 that embodies teachings of the present invention is shown in FIG. 6A. As shown therein, the semiconductor chip support structure 80 may include a substantially planar carrier member 82, which may be configured as an elongated or ribbon-shaped structure. The semiconductor chip support structure 80 may include a plurality of protective members 40 integrally formed with the substantially planar carrier member 82.

Each protective member 40 may be configured to protect at least a portion of an active surface of a semiconductor chip, such as the semiconductor chip 10 shown in FIGS. 1A-1B, when the semiconductor chip is attached to the protective member 40. The protective member 40 also may be configured to expose a plurality of electrically conductive pads on the active surface of the semiconductor chip 10 through the protective member 40 when the semiconductor chip 10 is attached to the protective member 40. As seen in FIGS. 6A-6B, each protective member 40 may have a substantially rectangular or frame shape substantially defined by an inner boundary 42 and a peripheral boundary 44 of the protective member 40. The inner boundary 42 of the protective member 40 may be continuous or substantially continuous and may define an aperture 86 extending through the protective member 40. The plurality of electrically conductive pads on the active surface of a semiconductor chip 10 may be exposed through the aperture 86 of the protective member 40 when the semiconductor chip 10 is attached by its active surface 12 to the protective member 40. Furthermore, each protective member 40 may include a cantilevered portion 46 that extends laterally beyond the lateral boundary of a semiconductor chip 10 when the semiconductor chip is attached to the protective member 40. The protective member 40 also may include a cantilevered portion 46 that extends laterally beyond every point along the lateral boundary of the semiconductor chip 10 when the semiconductor chip 10 is attached to the protective member 40.

An enlarged view of a protective member 40 of the semiconductor chip support structure 80 is shown in FIG. 6B. Each protective member 40 may be secured to the substantially planar carrier member 82 by at least one securing member 88. The protective member 40 shown in FIG. 6B is secured, by way of example only, to the substantially planar carrier member 82 with four securing members 88.

A semiconductor chip may be secured to each protective member 40 of the plurality of protective members 40 carried by the support structure 80 in the same manner as that discussed previously herein in relation to the CSP semiconductor device 36 shown in FIGS. 2A-2C. If a semiconductor chip 10 is attached to each of the protective members 40 of the semiconductor chip support structure 80, a plurality of CSP semiconductor devices 36 (FIGS. 2A-2C) may be provided on the semiconductor support structure 80, each of the CSP semiconductor devices 36 being secured to the substantially planar carrier member 82 by at least one securing member 88. Additional fabrication and packaging processes then may be performed on the plurality of CSP semiconductor devices 36 while they are attached to the semiconductor chip support structure 80. The CSP semiconductor devices 36 also may be tested while they are attached to the semiconductor chip support structure 80.

The semiconductor chip support structure 80 may include a plurality of index holes 90, which may be used for manipulation of the semiconductor chip support structure 80 by conventional mechanized manufacturing or testing equipment or for aligning the semiconductor chip support structure 80 relative to such manufacturing or testing equipment, such techniques being well-developed for use with lead frame-mounted semiconductor chips. Accordingly, each semiconductor chip support structure 80 bearing a plurality of semiconductor chips secured to protective members 40 may function in a manner equivalent to a lead frame strip. Each CSP semiconductor device 36 may be removed from the semiconductor chip support structure 80 by severing the securing members 88 shown in FIG. 6B proximate to each protective member 40. The securing members 88 may be severed by, for example, a punch, router or saw, by etching or stamping, or by use of a laser beam or a water jet.

The semiconductor chip support structure 80 may be formed by providing a substantially planar carrier member 82 and punching or stamping the other features of the support member 80 into or through the substantially planar carrier member 82. For example, the substantially planar carrier member 82 may include a thin piece of sheet metal, and the apertures 86, the index holes 90, and several apertures 87 surrounding each protective member 40 may be punched through the thin piece of sheet metal using an automated punch press, or by stamping or etching, as known in the art. The thin piece of sheet metal may be stamped with a press to provide non-planar features to the semiconductor chip support structure 80. Such punching and stamping processes are known in the art. It should be understood that the substantially planar carrier member 82 may be punched and stamped to provide a plurality of protective members including features that may or may not be substantially planar, although the remainder of the substantially planar carrier member 82 may remain substantially planar. While the protective members 40 shown in FIGS. 6A-6B are substantially planar, protective members having configurations that are not substantially planar and that embody teachings of the present invention are described subsequently herein. Semiconductor chip support structures-that include a plurality of protective members having non-planar structural features integrally formed therewith are also considered to be within the scope of the present invention.

Other configurations of semiconductor chip support structures may be provided that embody teachings of the present invention. For example, the semiconductor chip support structure need not be configured to have an elongated or ribbon-shape, and the plurality of protective members integrally formed therewith need not be arranged in a single row as shown in FIG. 6A. Semiconductor chip support structures that embody teachings of the present invention may be configured to have a square shape, a round shape, or any other shape. Furthermore, the plurality of protective members may be arranged in either an arbitrary pattern or an ordered array of rows and columns on the semiconductor chip support structure.

Semiconductor chip support structures that embody teachings of the present invention may include protective members having configurations other than the substantially rectangular frame-shaped configuration of the protective members 40 shown in FIGS. 6A-6B. For example, a portion of another semiconductor chip support structure 92 that embodies teachings of the present invention is shown in FIG. 7. The semiconductor chip support structure 92 may include a substantially planar carrier member 93 that is substantially similar to the substantially planar carrier member 82 shown in FIG. 6A. The semiconductor chip support structure 92, however, may include a plurality of protective members 94, each of which may include a first substantially C-shaped portion 96A and a second substantially C-shaped portion 96B. Only one protective member 94 is shown in FIG. 7. The first substantially C-shaped portion 96A may be attached to the substantially planar carrier member 93 by a first securing member 100A, and the second substantially C-shaped portion 96B may be attached to the substantially planar carrier member 93 by a second securing member 100B. Alternatively, the first substantially C-shaped portion 96A and the second substantially C-shaped portion 96B each may be secured to the substantially planar carrier member 93 with a plurality of securing members.

The semiconductor chip support structure 92 also may include a plurality of apertures 102, each of which may be at least partially defined by the space between the first substantially C-shaped portion 96A and the second substantially C-shaped portion 96B. Each aperture 102 may be configured to expose a plurality of electrically conductive pads on an active surface of a semiconductor chip through the protective member 94 when the semiconductor chip is attached to the protective member 94. Furthermore, each protective member 94 may be configured such that the first substantially C-shaped portion 96A and the second substantially C-shaped portion 96B of the protective member each include a cantilevered portion that is configured to extend laterally beyond the lateral boundary of a semiconductor chip when the semiconductor chip is attached to the protective member 94. The semiconductor chip may be attached to the first substantially C-shaped portion 96A and the second substantially C-shaped portion 96B of the protective member 94 by, for example, using an adhesive in the same manner as that discussed previously herein in relation to the protective member 40 shown in FIGS. 2A-2C.

A semiconductor chip may be secured to each protective member 94 of the semiconductor chip support structure 92 in the same manner as that discussed previously herein in relation to the semiconductor chip support structure 80 shown in FIGS. 6A-6B to provide a plurality of CSP semiconductor devices on the semiconductor support structure 92. Additional manufacturing processes or steps then may be performed on the plurality of CSP semiconductor devices while they are attached to the semiconductor chip support structure 92. Each of the CSP semiconductor devices then may be singulated from the semiconductor chip support structure 92.

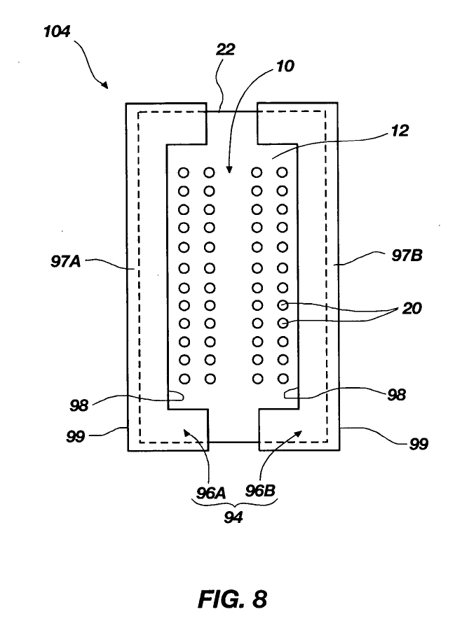

Another CSP semiconductor device 104 that embodies teachings of the present invention is shown in FIG. 8. The CSP semiconductor device 104 includes a semiconductor chip 10 as shown in FIGS. 1A-1B and the protective member 94 shown in FIG. 7. The protective member 94 may be attached to the active surface 12 of the semiconductor chip 10 and configured to protect at least a portion of the active surface 12 of the semiconductor chip 10. Furthermore, the protective member 94 may be attached to the semiconductor chip 10 such that the protective member 94 substantially covers a pad-free region 16 (FIG. 1A) of the active surface 12 of the semiconductor chip 10, and such that a plurality of electrically conductive pads are exposed through the aperture of the protective member 94 substantially defined by inner boundary 98 when the protective member 94 is attached to the semiconductor chip 10. The first substantially C-shaped portion 96A may include a first cantilevered portion 97A and the second substantially C-shaped portion 96B may include a second cantilevered portion 97B. Each of the first cantilevered portion 97A and the second cantilevered portion 97B may extend laterally beyond a substantial section of the lateral boundary 22 of the semiconductor chip 10 to provide a protective outer perimeter 99. For example, the first-cantilevered portion 97A and the second cantilevered portion 97B may extend laterally beyond about 80 percent of the lateral boundary 22 of the semiconductor chip 10.

In this manner, the protective member 94 is configured to protect at least a portion of the active surface 12 of the semiconductor chip 10 and to expose a plurality of the electrically conductive pads 30 when the protective member 94 is attached to the semiconductor chip 10 in substantially the same manner as that described previously herein in reference to the protective member 40 shown in FIGS. 2A-2C. Furthermore, in this configuration the protective member 94 may be used both to distribute power to the semiconductor chip 10 and to electrically ground or bias the semiconductor chip 10 in addition to protect the semiconductor chip 10 from damage. For example, the first substantially C-shaped portion 96A and the second substantially C-shaped portion 96B each may be electrically conductive and each may electrically communicate with electrically conductive features or traces on the higher level substrate 66. Furthermore, one of the first substantially C-shaped portion 96A and the second substantially C-shaped portion 96B may communicate electrically with an electrically conductive pad 30 (FIG. 1B) of the semiconductor chip 10 that is configured to distribute electrical power or provide a ground or bias to the semiconductor chip 10. Furthermore, each of the first substantially C-shaped portion 96A and the second substantially C-shaped portion 96B may be secured to the higher level substrate 66 by, for example, using an electrically conductive adhesive to provide mechanical affixation while providing an electrical path. In this configuration, one of the first substantially C-shaped portion 96A and the second substantially C-shaped portion 96B may be used to electrically ground or bias the semiconductor chip attached thereto, and the other one of the first substantially C-shaped portion 96A and the second substantially C-shaped portion 96B may be used to distribute power to the semiconductor chip.

A portion of another semiconductor chip support structure 106 that embodies teachings of the present invention is shown in FIG. 9. The semiconductor chip support structure 106 may include a substantially planar carrier member 108 that is substantially similar to the substantially planar carrier member 82 shown in FIG. 6A. The semiconductor chip support structure 106, however, may include a plurality of polygonal-shaped protective members 110, one of which is illustrated in FIG. 9. As shown therein, each polygonal-shaped protective member 110 may include cantilevered portions that are configured to extend laterally beyond the lateral boundary of a semiconductor chip 10 when the semiconductor chip 10 is attached to the protective member 110. The cantilevered portions include two end flanges 114 and two side flanges 15. Each of the protective members 110 of the semiconductor chip support structure 106 may be secured to the substantially planar carrier member 108 by at least one securing member 116.

The semiconductor chip support structure 106 also may include a plurality of apertures 118, each of which may be at least partially defined by at least a portion of a continuous inner boundary 111 of one of the protective members 110. Furthermore, each aperture 118 may be configured to expose a plurality of electrically conductive pads on an active surface of a semiconductor chip through the substantially planar carrier member 108 when the semiconductor chip is attached to the corresponding protective member 110.

A plurality of semiconductor chips may be attached to the semiconductor support structure, one semiconductor chip being attached to each of the protective members 1 1 0 such that the end flanges 114 and the side flanges 115 of each protective member 110 extend laterally beyond the lateral boundary of the corresponding semiconductor chip. The semiconductor chips may be attached to the protective members I 10 in the same manners as those discussed previously herein in relation to the CSP semiconductor device 36 shown in FIGS. 2A-2C. After the semiconductor chips have been attached to the protective members 110, each semiconductor chip together with the corresponding protective member 110 secured thereto may be singulated from the semiconductor chip support structure 106 to provide individual CSP semiconductor devices that embody teachings of the present invention.

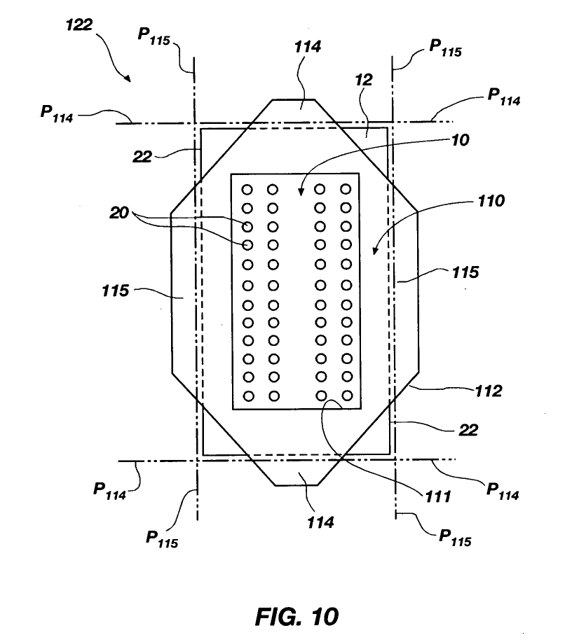

Another CSP semiconductor device 122 that embodies teachings of the present invention is shown in FIG. 10. The CSP semiconductor device 122 may include the semiconductor chip 10 shown in FIGS. 1A-1B and the protective member 110 shown in FIG. 9. The protective member 110 may be attached to the semiconductor chip 10 and configured to protect at least a portion of the active surface 12 of the semiconductor chip 10 in substantially the same manner as that described previously herein in relation to the CSP semiconductor device 36 shown in FIGS. 2A-2C. Furthermore, the protective member 110 may be configured to expose a plurality of the electrically conductive pads 30 when the protective member 110 is attached to the semiconductor chip 10.

As seen in FIG. 10, the protective member 110 may have a polygonal shape substantially defined by an inner boundary 111 and a peripheral boundary 112 of the protective member 110. The inner boundary 111 of the protective member 110 may be continuous and may define an aperture extending through the protective member 110. The peripheral boundary 112 of the protective member 110 also may be continuous. The protective member 110 may be attached to the semiconductor chip 10 such that the protective member 110 substantially covers a pad-free region 16 (FIG. 1A) of the active surface 12 the semiconductor chip 10, and such that a plurality of electrically conductive pads are exposed through the aperture of the protective member 110. At least a portion of each of the end flanges 114 and the side flanges 115 may extend laterally beyond the lateral boundary 22 of the semiconductor chip 10. Together, the end flanges 114 and the side flanges 115 may extend laterally beyond a substantial portion of the lateral boundary 22 of the semiconductor chip 10.

In this configuration, the protective member 110 may be attached to the semiconductor chip 10 such that the protective member 110 substantially covers a pad-free region 16 (FIG. 1A) of the active surface 12 of the semiconductor chip 10. In addition, a plurality of the electrically conductive pads 30 may be exposed through the aperture of the protective member 110 defined by the continuous inner boundary 111 when the protective member 110 is attached to the semiconductor chip 10. In this manner, the protective member 110 is configured to protect at least a portion of the active surface 12 of the semiconductor chip 10 and to expose a plurality of the electrically conductive pads 30 when the protective member 10 is attached to the semiconductor chip 10 in the same manner as that described previously herein in relation to the CSP semiconductor device 36 shown in FIGS. 2A-2C.

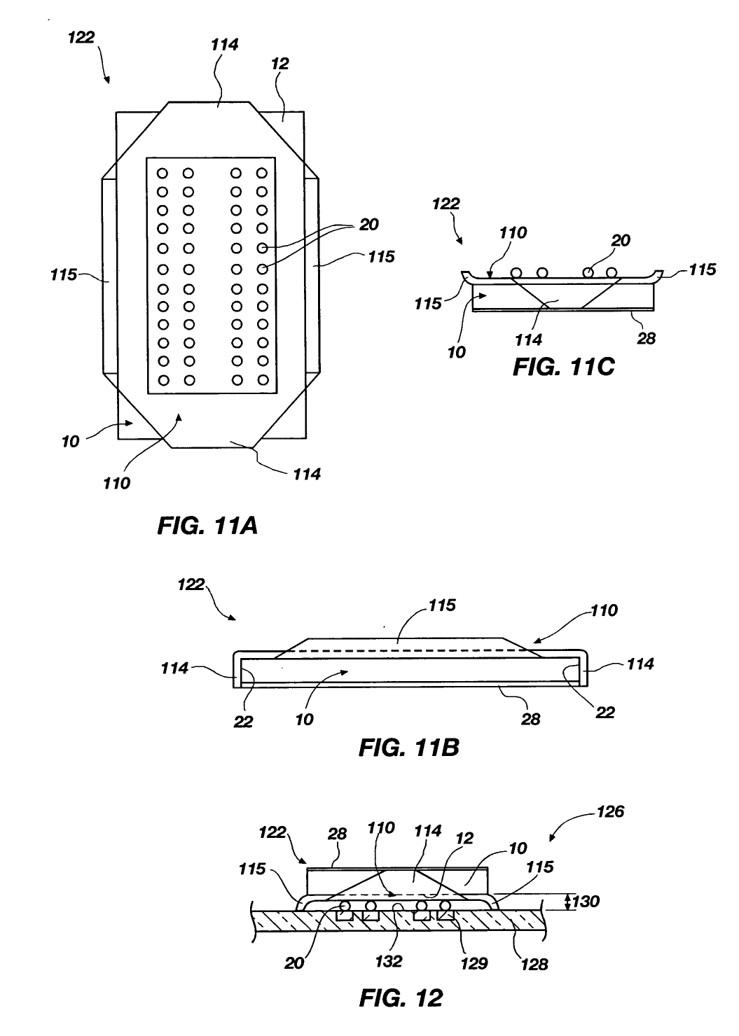

In an alternative configuration, each end flange 114 of the protective member 10 may be folded along a corresponding plane P₁₁₄, and each side flange may be folded along a corresponding plane P₁₁₅ (planes P₁₁₄ and planes P₁₁₅ are shown in FIG. 10) to provide an CSP semiconductor device 122 shown in FIGS. 11A-11C that embodies teachings of the present invention. As best seen in FIGS. 11B-11C, each end flange 114 of the protective member 110 may be folded in a direction towards the semiconductor chip 10 such that each end flange 114 is disposed adjacent a portion of the lateral boundary 22 of the semiconductor chip 10. Furthermore, each side flange 115 of the protective member 110 may be folded in a direction away from the semiconductor chip 10 as illustrated in FIGS. 11B-11C.

Flanges folded in a direction perpendicular to the major plane of protective member 110 such that flanges are disposed adjacent a portion of the location of lateral boundary 22 of the semiconductor chip 10 may be used to receive semiconductor chip 10 within the protective member 110 and to secure protective member 110 (such with a suitable adhesive preapplied to the flanges) to the semiconductor chip 10. Furthermore, flanges folded in a direction towards the semiconductor chip 10 such that flanges are disposed adjacent a portion of the lateral boundary 22 of the semiconductor chip 10 may provide protection to at least a portion of the lateral boundary 22 of the semiconductor chip 10 or to at least a portion of the passivated, back side surface 28 of the semiconductor chip 10. Flanges folded in a direction away from the semiconductor chip 10 such as the side flanges 115 may be used to provide a selected standoff distance between the active surface 12 of the semiconductor chip 10 and a higher level substrate to which the CSP semiconductor device 122 is to be attached. Furthermore, flanges folded in a direction away from the semiconductor chip 10 such as the side flanges 115 may be used to electrically ground the semiconductor chip 10 of the CSP semiconductor device 122 or to distribute electrical power to the semiconductor chip 10 of the CSP semiconductor device 122 through such a higher level substrate by contact with conductors carried thereon.

Another semiconductor device assembly 126 that embodies teachings of the present invention is shown in FIG. 12. The semiconductor device assembly 126 includes the CSP semiconductor device 122 shown in FIGS. 11A-11C and a higher level substrate 128 to which the CSP semiconductor device 122 has been attached and electrically coupled. The CSP semiconductor device 122 may be positioned relative to the higher level substrate 128 such that each conductive electrically conductive bump 20 electrically communicates with an electrical structure 129 of the higher level substrate 128. As seen in FIG. 12, the side flanges 115 of the CSP semiconductor device 122 may provide a selected standoff distance 130 between the active surface 12 of the semiconductor chip 10 and a surface 132 of the higher level substrate 128. The selected standoff distance 130 may be selected to be slightly less than the distance the electrically conductive bumps 20 extend from the active surface 12 of the semiconductor chip 10 in a direction perpendicular thereto to ensure electrical contact and communication between the electrically conductive bumps 20 and the corresponding electrical structures 129 of the higher level substrate 128 when the CSP semiconductor device 122 is placed against the higher level substrate 128 such that the side flanges 115 of the CSP semiconductor device 122 contact the surface 132 of the higher level substrate 128. With this approach, the side flanges 115 may also be used to provide a uniform standoff distance during reflow of solder used for conductive bumps 20 or curing of conductive bumps if formed of a conductive or conductor-filled adhesive such as an epoxy. The higher level substrate 128 may be a carrier substrate such as a printed circuit board or an interposer, and may include additional electrical structures and circuitry (not shown).

An adhesive applied to either the side flanges 115 of the CSP semiconductor device 122, to the surface 132 of the higher level substrate 128, or to both the side flanges 115 and the surface 132 may be used to secure the CSP semiconductor device 122 to the higher level substrate 128. An underfill material optionally may be provided between at least a portion of the CSP semiconductor device 122 and the higher level substrate 128, as is known in the art.

In further embodiment of the present invention, each end flange 114 and each side flange 115 may be folded in a direction towards the semiconductor chip 10 such that each end flange 114 is disposed adjacent a portion of the lateral boundary 22 of the semiconductor chip 10, or each end flange 114 and each side flange 115 may be folded in a direction away from the semiconductor chip 10. Flanges may be sized to allow the flanges to be folded such that the flanges cover only a portion of the lateral boundary 22 of the semiconductor chip 10. Alternatively, flanges may be sized to enable the flanges to be folded such that the flanges cover the entire portion of the lateral boundary 22 of the semiconductor chip 10.

As described previously herein, the protective member of a CSP semiconductor device that embodies teachings of the present invention may protect at least a portion of an active surface of a semiconductor chip attached thereto from damage. Furthermore, the protective member of a CSP semiconductor device that embodies teachings of the present invention may be used to electrically ground a semiconductor chip attached thereto, or to distribute electrical power to a semiconductor chip attached thereto. The protective member of a CSP semiconductor device that embodies teachings of the present invention also may be used to position the CSP semiconductor device relative to a substrate or to align the CSP semiconductor device relative to manufacturing and testing equipment.

During fabrication of a semiconductor device, the semiconductor device may be permanently or temporarily attached to a substrate or other structure to facilitate further manufacturing processes or to facilitate testing of the semiconductor device. Such a substrate may be configured to support a plurality of semiconductor devices. Each semiconductor device may be subsequently removed from the substrate, or each semiconductor device may be singulated from the substrate such that at least a portion of the substrate becomes part of the final product that includes the semiconductor device. The protective member of a CSP semiconductor device that embodies teachings of the present invention, such as the CSP semiconductor device 36 shown in FIGS. 2A-2C, may be used to position the CSP semiconductor device at a precise location on such a substrate or other structure.

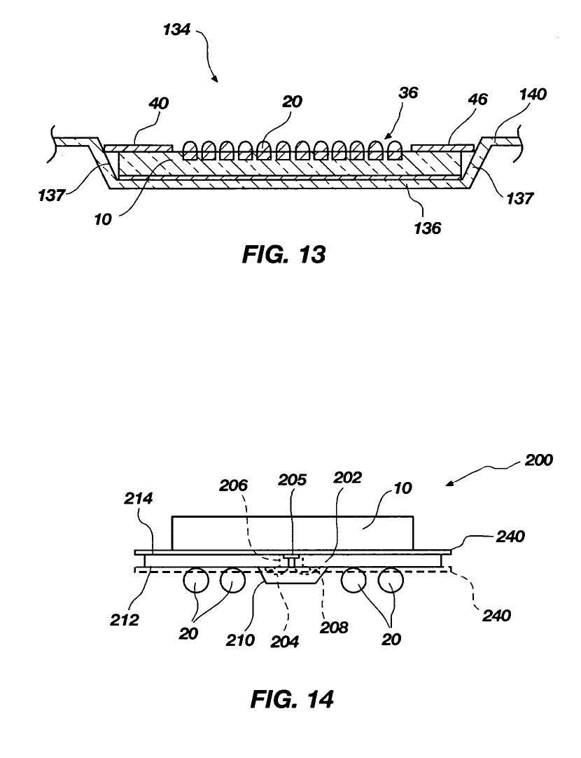

For example, FIG. 13 illustrates a portion of another semiconductor device 134 that embodies teachings of the present invention. The semiconductor device 134 includes the CSP semiconductor device 36 shown in FIGS. 2A-2C and a housing 136. The housing 136 may include a recessed portion surrounded by tapered sidewalls 137 as shown in FIG. 13. While only one CSP semiconductor device 36 and one recessed portion of the housing 136 are shown in FIG. 13, it should be understood that the semiconductor device 134 may include a plurality of CSP semiconductor devices 36, each disposed within a recessed portion of the housing 136.

The CSP semiconductor device 36 may be precisely positioned within the recessed portion of the housing 136 utilizing the protective member 40 of the CSP semiconductor device 36. The protective member 40 of the CSP semiconductor device 36 may be configured to engage the tapered sidewalls 137 at a selected position when the CSP semiconductor device 36 is positioned within the recessed portion of the housing 136. In this manner, the protective member 40 may be used to precisely position the CSP semiconductor device at a predetermined location within the housing 136. The CSP semiconductor device 36 optionally may be removed from the housing 136 subsequent to performing further manufacturing processes or testing of the device. Alternatively, the CSP semiconductor device 36 may be secured to the housing 136 at the periphery of protective member 40 using a suitable adhesive preapplied to either protective member 40 or the tapered sidewalls 137 of housing 136, and the assembly singulated from a carrier portion 140 from which housing 136 is formed, as by stamping, molding, etc., such that housing 136 becomes part of the final product that includes the CSP semiconductor device 36.

Referring to FIG. 14 of the drawings, yet another embodiment of the present invention is depicted. In this embodiment, BGA assembly 200 comprises a semiconductor chip 10 attached to an interposer substrate 202 by wire bonds 204 extending from bond pads 205 through a slot 206 to terminals 208 (all shown in broken lines) on interposer substrate 202, the wire bonds 204 and adjacent terminals 208 on interposer substrate 202 being encapsulated with a dielectric material 210. Conductive bumps 20 projecting from interposer substrate 202 on an opposing side of interposer substrate 202 from semiconductor chip 10 are connected to terminals 208 by conductive traces (not shown). A protective member 240 may be affixed to a lower surface 212 of interposer substrate 202 surrounding conductive bumps 20 as shown in broken lines, or to an upper surface 214 of interposer substrate 202 about semiconductor chip 10 as shown in solid lines. In such a manner, BGA assembly 200, and specifically semiconductor chip 10 and conductive bumps 20, may be effectively protected from undesirable lateral contact by, for example, pick and place equipment.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. A CSP semiconductor device comprising:
a semiconductor chip comprising:
an active surface, the active surface being circumscribed by a lateral boundary of the semiconductor chip; and
at least one electrically conductive pad disposed on the active surface; and
a protective member attached to the active surface of the semiconductor chip, the at least one electrically conductive pad being exposed through the protective member, the protective member comprising a cantilevered peripheral portion that extends laterally beyond at least a portion of the lateral boundary of the semiconductor chip.

2. The CSP semiconductor device of claim 1, wherein the active surface of the semiconductor chip comprises a conductive pad region and a pad-free region, the at least one electrically conductive pad being located within the conductive pad region, the protective member substantially covering the pad-free region of the active surface of the semiconductor chip.

3. The CSP semiconductor device of claim 2, wherein the conductive pad region of the active surface of the semiconductor chip includes an inner region of the active surface of the semiconductor chip and the pad-free region includes a peripheral region of the active surface of the semiconductor chip.

4. The CSP semiconductor device of claim 1, wherein the cantilevered portion of the protective member extends laterally beyond an entirety of the lateral boundary of the semiconductor chip.

5. The CSP semiconductor device of claim 1, wherein at least a portion of the protective member is non-planar.

6. The CSP semiconductor device of claim 5, wherein the cantilevered portion of the protective member comprises at least one flange, the at least one flange being disposed at an angle relative to the plane of the active surface of the semiconductor chip.

7. The CSP semiconductor device of claim 6, wherein the at least one flange is oriented to protect at least a portion of a lateral surface of the semiconductor chip.

8. The CSP semiconductor device of claim 6, wherein the at least one flange is oriented to provide a selected standoff between the semiconductor chip and a higher level substrate adjacent the active surface.

9. The CSP semiconductor device of claim 1, further comprising at least one electrically conductive bump, the at least one electrically conductive bump communicating electrically with the at least one electrically conductive pad.

10. The CSP semiconductor device of claim 9, wherein the CSP semiconductor device is configured as a flip-chip CSP semiconductor device.

11. The CSP semiconductor device of claim 1, wherein the protective member comprises a laminate structure.

12. The CSP semiconductor device of claim 11, wherein the laminate structure comprises an adhesive layer.

13. The CSP semiconductor device of claim 1, wherein the protective member has a nonrectangular, polygonal shape.

14. The CSP semiconductor device of claim 13, wherein the protective member has a substantially rectangular shape.

15. The CSP semiconductor device of claim 13, wherein the protective member comprises a first C-shaped portion and a facing, second C-shaped portion.

16. The CSP semiconductor device of claim 1, wherein the protective member comprises at least one of a metal, a ceramic, and a polymer.

17. The CSP semiconductor device of claim 1, wherein the protective member is electrically connected to circuitry of the semiconductor chip configured to provide electrical power to the semiconductor chip when the semiconductor chip is attached to a higher level substrate.

18. The CSP semiconductor device of claim 1, wherein the protective member is electrically connected to the semiconductor chip and configured to electrically ground or bias the semiconductor chip when the semiconductor chip is attached to a higher level substrate.

19. The CSP semiconductor device of claim 1, wherein the protective member comprises a first portion electrically connected to circuitry of the semiconductor chip and configured to provide electrical power to the semiconductor chip when the semiconductor chip is attached to a higher level substrate and a second portion electrically connected to the semiconductor chip and configured to electrically ground the semiconductor chip when the semiconductor chip is attached to a higher level substrate.

20. The CSP semiconductor device of claim 1, wherein the protective member comprises at least two segments.

21. The CSP semiconductor device of claim 9, wherein the protective member is of a thickness less than a height of the at least one conductive bump.

22. The CSP semiconductor device of claim 1, further comprising a packaging material disposed over a back side surface and lateral surfaces of the semiconductor chip, and having an outer lateral boundary substantially coincident with an outer lateral periphery of the protective member.

23. A semiconductor device assembly comprising:
a CSP semiconductor device comprising:
a semiconductor chip comprising:
an active surface, the active surface being circumscribed by a lateral boundary of the semiconductor chip; and
a plurality of electrically conductive pads disposed on the active surface; and
a protective member attached to the active surface of the semiconductor chip, the plurality of electrically conductive pads being exposed through the protective member, the protective member comprising a cantilevered, peripheral portion that extends laterally beyond at least a portion of the lateral boundary of the semiconductor chip; and
a higher level substrate comprising a plurality of conductive structures, the CSP semiconductor device being attached to the higher level substrate, each electrically conductive pad of the semiconductor chip electrically communicating with a conductive structure of the higher level substrate.

24. The semiconductor device assembly of claim 23, wherein the protective member is disposed between the semiconductor chip and the higher level substrate and attached to the higher level substrate.

25. The semiconductor device assembly of claim 24, further comprising an adhesive material disposed between the protective member and the higher level substrate.

26. The semiconductor device assembly of claim 25, wherein the adhesive material comprises an epoxy material.

27. The semiconductor device assembly of claim 25, wherein the protective member is electrically conductive and electrically isolated from the active surface, and the adhesive material is electrically conductive and contacts at least one conductive structure of the higher level substrate.

28. The semiconductor device assembly of claim 27, wherein the protective member is segmented, and conductive structures of the higher level substrate are connected to the protective member segments through discrete portions of the electrically conductive adhesive to provide ground or bias and power to the semiconductor chip.

29. The semiconductor device assembly of claim 23, wherein the CSP semiconductor device is configured as a flip-chip CSP semiconductor device.

30. The semiconductor device assembly of claim 23, further comprising a plurality of electrically conductive bumps, each electrically conductive bump providing electrical communication between an electrically conductive pad of the semiconductor chip and an electrically conductive structure of the higher level substrate.

31. The semiconductor device assembly of claim 30, wherein each electrically conductive bump comprises one of a conductive solder material and a conductive or conductor-filled epoxy material.

32. The semiconductor device assembly of claim 30, further comprising an anisotropically conductive film disposed between the active surface and the higher level substrate for providing electrical communication between at least one electrically conductive pad of the semiconductor chip and at least one electrically conductive structure of the higher level substrate.

33. The semiconductor device assembly of claim 23, further comprising a packaging material, the packaging material covering at least a portion of at least one of a back side surface of the semiconductor chip and a lateral surface of the semiconductor chip.

34. The semiconductor device assembly of claim 33, wherein the packaging material comprises a polymer material.

35. The semiconductor device assembly of claim 34, wherein a lateral outer periphery of the packaging material is substantially coincident with a lateral periphery of the protective member.

36. The semiconductor device assembly of claim 23, wherein the higher level substrate comprises a carrier substrate in the form of one of a printed circuit board, and an interposer.

37. The semiconductor device assembly of claim 23, wherein the cantilevered portion of the protective member of the CSP semiconductor device extends laterally beyond an entirety of the lateral boundary of the semiconductor chip.

38. A semiconductor chip support structure comprising:
a substantially planar carrier member;
at least one protective member attached to the substantially planar carrier member, the at least one protective member being configured to protect at least a portion of an active surface of a semiconductor chip and to expose at least one electrically conductive pad on the active surface through the at least one protective member when the semiconductor chip is attached to the at least one protective member, the at least one protective member being sized and configured to provide a cantilevered portion to extend laterally beyond a lateral boundary of the semiconductor chip when attached thereto.

39. The semiconductor chip support structure of claim 38, further comprising at least one aperture passing through the substantially planar carrier member, the at least one aperture defining the at least one protective member, the at least one protective member being integrally formed with the substantially planar carrier member.

40. The semiconductor chip support structure of claim 39, wherein the substantially planar carrier member and the at least one protective member comprise one of a metal, a ceramic, and a polymer.

41. The semiconductor chip support structure of claim 38, wherein the substantially planar carrier member is configured as an elongated strip.

42. The semiconductor chip support structure of claim 38, wherein the at least one protective member comprises a plurality of protective members disposed in one of a line and an array of rows and columns.

43. The semiconductor chip support structure of claim 38, wherein the at least one protective member is planar.

44. The semiconductor chip support structure of claim 38, wherein the at least one protective member is disposed within an opening in the substantially planar carrier member and secured thereto by at least one segment of material.

45. The semiconductor chip support structure of claim 38, wherein the at least one protective member has a nonrectangular polygonal shape.

46. The semiconductor chip support structure of claim 38, wherein the at least one protective member has a substantially rectangular shape.

47. The semiconductor chip support structure of claim 38, wherein the at least one protective member comprises a first C-shaped portion and a facing, second C-shaped portion.

48. The semiconductor chip support structure of claim 38, further comprising at least one semiconductor chip attached to the at least one protective member, the at least one semiconductor chip comprising:
an active surface, the active surface being circumscribed by a lateral boundary of the semiconductor chip, the cantilevered portion of the at least one protective member extending laterally beyond the lateral boundary of the semiconductor chip; and
a plurality of electrically conductive pads disposed on the active surface, the plurality of electrically conductive pads being exposed through the at least one protective member.

49. A method of packaging at least one semiconductor chip comprising:
providing at least one semiconductor chip, comprising:
an active surface, the active surface being circumscribed by a lateral boundary of the at least one semiconductor chip; and
at least one electrically conductive pad disposed on the active surface;
attaching at least one protective member to the active surface of the at least one semiconductor chip such that the at least one electrically conductive pad is exposed through the at least one protective member and at least a portion of a periphery of the at least one protective member extends laterally beyond the lateral boundary of the at least one semiconductor chip.

50. The method of claim 49, wherein attaching the at least one protective member comprises providing a layer of double-sided adhesive tape between the at least one protective member and the at least one semiconductor chip.

51. The method of claim 49, further comprising providing a packaging material on at least a portion of at least one of a back side surface of the at least one semiconductor chip and a lateral surface of the at least one semiconductor chip.

52. The method of claim 51, wherein providing a packaging material comprises molding a polymer material on at least a portion of at least one of a back side surface of the at least one semiconductor chip and a lateral surface of the at least one semiconductor chip.

53. The method of claim 52, wherein molding a polymer material comprises one of injection molding, pot molding, and transfer molding.

54. The method of claim 53, further comprising defining an outer lateral boundary of the packaging material to be substantially coincident and in contact with a peripheral edge of the at least one protective member.

55. The method of claim 49, further comprising attaching the at least one protective member to a higher level substrate.

56. The method of claim 55, wherein attaching the at least one protective member to a higher level substrate comprises:
applying a curable adhesive to at least one of the at least one protective member and the higher level substrate;
adjoining the at least one protective member to the higher level substrate; and
curing the curable adhesive.

57. The method of claim 56, further comprising configuring the at least one protective member to be wettable relative to the curable adhesive.

58. The method of claim 57, wherein configuring the at least one protective member to be wettable relative to the curable adhesive comprises at least one of providing a layer of wettable material on a surface of the at least one protective member and forming the at least one protective member of a wettable material.

59. A method for packaging a plurality of semiconductor devices comprising:
providing a semiconductor chip support structure, comprising:
a substantially planar carrier member; and
a plurality of protective members attached to the substantially planar carrier member, each protective member being configured to protect at least a portion of an active surface of a semiconductor chip and to expose at least one electrically conductive pad of a semiconductor chip through the plurality of protective members when a semiconductor chip is attached to each protective member, each protective member comprising a cantilevered portion configured to extend laterally beyond at least a portion of a lateral boundary of the semiconductor chip when each protective member is secured to the semiconductor chip;
providing a plurality of semiconductor chips, each semiconductor chip comprising:
an active surface, the active surface being circumscribed by a lateral boundary of the semiconductor chip; and
a plurality of electrically conductive pads disposed on the active surface; and
attaching each semiconductor chip of the plurality of semiconductor chips to one protective member of the plurality of protective members such that at least one of the electrically conductive pads is exposed through each protective member and a portion of each protective member extends laterally beyond at least a portion of the lateral boundary of the semiconductor chip.

60. The method of claim 59, wherein providing a semiconductor chip support structure comprises:
providing a piece of sheet metal; and
forming a plurality of apertures through the piece of sheet metal to define the plurality of protective members.

61. The method of claim 59, further comprising stamping the semiconductor chip support structure with a die to provide nonplanar features to the plurality of protective members.

62. The method of claim 60, further comprising singulating each semiconductor chip with a protective member attached thereto from the substantially planar carrier member.

63. A BGA assembly, comprising:
a semiconductor chip;
an interposer substrate secured and electrically connected to the semiconductor chip;
a plurality of discrete conductive structures projecting from the interposer substrate on a side thereof opposite the semiconductor chip; and
a protective member secured to the interposer substrate and having a lateral periphery extending beyond at least a portion of a lateral periphery of the interposer substrate.

64. The BGA assembly of claim 63, wherein the protective member is secured to the side of the substrate opposite the semiconductor chip and substantially surrounds the plurality of discrete conductive structures.

65. The BGA assembly of claim 63, wherein the protective member is secured to the same side of the substrate as the semiconductor chip and extends about a substantial portion thereof.
